(19) United States
(12) Patent Application Publication
(10) Pub. No.: US 2009/0072312 A1
(43) Pub. Date: Mar. 19, 2009

(54) Metal High-K (MHK) Dual Gate Stress Engineering Using Hybrid Orientation (HOT) CMOS

(76) Inventors: Leland Chang, New York, NY (US); Shreesh Narasimha, Beacon, NY (US); Vijay Narayanan, New York, NY (US); Jeffrey W. Sleight, Ridgefield, CT (US)

Correspondence Address: Harrington & Smith, PC, 4 Research Drive, Shelton, CT, 06484-6212, US

(21) Appl. No.: 11/855,204

(22) Filed: Sep. 14, 2007

(51) Int. Cl. H01L 27/12; H01L 21/84

(52) U.S. Cl. 257/351; 438/154; 257/E21.7; 257/E27.112

(57) ABSTRACT

A hybrid orientation technology (HOT) CMOS structure is comprised of a tensile stressed NFET gate stack and a compressively stressed PFET gate stack, where each gate stack is comprised of a high dielectric constant oxide/metal, and where the source of the stress in the tensile stressed NFET gate stack and the compressively stressed PFET gate stack is the metal in the high-k metal gate stack.

### TECHNICAL FIELD

The exemplary embodiments of this invention relate generally to semiconductor devices, and more particularly to integrated semiconductor devices, such as complementary metal oxide semiconductor (CMOS) devices formed atop a substrate having a silicon-on-insulator (SOI) portion and a bulk-Si portion.

### BACKGROUND

Vertical stress techniques, such as SMT (stress memorization technique) are attractive for future CMOS generations as they may scale more favorably than techniques such as liner stress. In the area of metal gate CMOS, a new possibility for gate induced stress is possible. For work function control in metal gate CMOS, the concept of dual metal gate stacks is being pursued.

US 2007/0069298 A1 describes a method for fabricating a mobility enhancement by strained channel CMOSFET with single workfunction metal gate, comprising, providing a semiconductor substrate formed with regions of a PMOSFET and an NMOSFET. A compressively strained film is formed overlying the PMOSFET channel, and then gate dielectric layers are formed on the NMOSFET region and the compressively strained film, respectively. Gate electrodes are formed on the gate dielectric layers, and a cap layer is then formed overlying the NMOSFET region for producing a local tensile stress on a channel of the NMOSFET. The single workfunction metal gate is not only used alone but also with high-k materials. The gate electrode layer may comprise conventional materials such as poly-Si, poly-SiGe; materials having a Fermi level corresponding to the mid-gap of the semiconductor substrate such as TiN, Ti, TaN, Ta, W; or other materials have a suitable workfunction. TiN is suitable for use as gate electrodes due to its adhesion, matured manufacturing process, and thermal stability. Sometimes a W or Al layer may be provided on the TiN gate electrode to reduce resistance.

This approach uses overlayer stress, not stress from the metal gate itself, and does not cover hybrid orientation.

US 2006/0237801 A1 describes strained CMOS in which the metal gate electrode may have its workfunction tuned to compensate for a threshold voltage shift. Generally, this means that the workfunction of the gate electrode will be increased for strained-silicon NMOS to compensate for the reduction in the conduction band of the strained silicon channel. In other words, a metal may be chosen as the gate electrode which has a slightly higher workfunction to compensate for the threshold voltage shift. This compensation may be done in a variety of ways, including the selection of a metal with a higher workfunction for use as the gate electrode and by doping the chosen metal, either with diffusion or implantation.

This approach also does not use stress from the metal gate, but instead uses the workfunction of metal to compensate for overlayer stress. This approach also does not cover hybrid orientation.

U.S. Pat. No. 7,208,815 B2 describes a CMOS device which may have multiple crystal orientations. One logic gate in the substrate may comprise at least one N-FET on one crystal orientation and at least one P-FET on another crystal orientation. Metals used for the gate electrodes are selected from TaSiN, TaN, MoN for the metal gate of N-FET; and Ru, WN, TaAlN for the metal gate of P-FET.

This approach does not use stress from the metal gate. Also, different gate metals are used to adjust the workfunction, and are not deposited under stress.

US 2006/0071285 A1 describes a high-k strained dual gate CMOS device with selectively strained channels, formed in both NMOS and PMOS transistors, taking advantage of the replacement gate process and using dual metal types with the appropriate thermal expansion coefficients as fill metal for the gate trench process.

While this approach does use stress from the metal gate, it does not use a hybrid orientation. As a result, the stress impact in the PFET case will be very weak.

### SUMMARY

The foregoing and other problems are overcome, and other advantages are realized, in accordance with the exemplary embodiments of this invention.

In a first aspect thereof the exemplary embodiments of this invention provide a hybrid orientation technology CMOS structure comprised of a tensile stressed NFET gate stack and a compressively stressed PFET gate stack, where each gate stack is comprised of a high dielectric constant oxide/metal, and where the source of the stress in the tensile stressed NFET gate stack and the compressively stressed PFET gate stack is the metal in the high-k metal gate stack.

In another aspect thereof the exemplary embodiments of this invention provide a method in which is used to form a hybrid orientation technology CMOS structure. A SOI substrate is provided. The SOI is processed to provide a SOI region and a bulk Silicon region. A first dummy gate stack is formed on the SOI region and a second dummy gate stack is formed on the bulk Silicon region. An oxide layer is formed. A replacement gate process is used to remove the first and the second dummy gate stack. This leaves a first and second opening. A high dielectric constant gate oxide, a metal gate, and a metal fill are deposited into one of the openings to form an NFET gate stack that is tensile stressed. A high dielectric constant gate oxide, a metal gate, and a metal fill are deposited into the other opening to form a PFET gate stack that is compressively stressed.

### BRIEF DESCRIPTION OF THE DRAWINGS

The foregoing and other aspects of the embodiments of this invention are made more evident in the following Detailed Description, when read in conjunction with the attached Drawing Figures, wherein:

FIG. 1A-1F illustrate an exemplary process flow to form a HOT structure;

FIGS. 2A and 2B illustrate enlarged cross-sections of Type A and Type B HOT structures, respectively.

FIGS. 3A-3E illustrate an exemplary replacement gate process flow to form a tensile stressed NFET gate stack and a compressively stressed PFET gate stack, where the source of the stress is the metal in a high-k metal gate stack.

FIG. 4 shows a logic flow diagram of a method in accordance with an exemplary embodiment of this invention to form a hybrid orientation technology CMOS structure.

### DETAILED DESCRIPTION

In the exemplary embodiments of this invention the stress in NMOS and PMOS gate stack metals is intentionally engineered to improve device performance. In addition, the improvements made to the gate stack metals are combined with hybrid orientation technology (HOT) to maximize the vertical stress performance coupling in the PFET device.

The exemplary embodiments of this invention create a CMOS structure with an tensile stressed NFET gate stack and a compressively stressed PFET gate stack, where the source of the stress is the metal in a high-k metal gate stack. Stress formed in the gate may be expected to scale more favorably with reduced pitch than stress techniques that involve the use of a liner (e.g., a dual stress liner, DSL, whereby a tensile liner, usually a nitride, is placed over an NFET and a compressive liner is placed over a PFET).

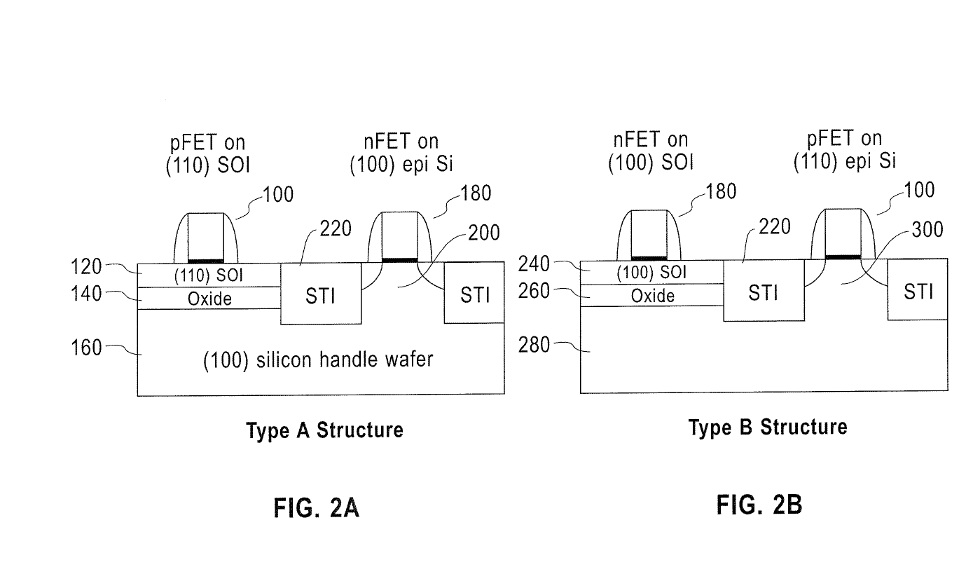

By way of introduction, reference is made to FIGS. 2A and 2B for showing Type A and Type B HOT structures, respectively. FIG. 2A shows a PFET 100 on a SOI structure comprised of a (110) Si layer 120, an oxide layer 140 and a (100) bulk Silicon handle wafer 160. An NFET 180 is instead on (100) epitaxial Silicon 200. Shallow trench isolation (STI) regions 220 separate the PFET 100 and the NFET 180. FIG. 2B shows a reverse situation, with the NFET 180 on the SOI structure comprised of a (100) Si layer 240, oxide 260 and underlying handle wafer 280. The PFET 100 in this case is on (110) epitaxial Si 300.

In both cases the PFET 100 is on the (110) Si surface and the NFET 180 is on the (100) Si surface to obtain enhanced performance. The current flow direction on both the (110) and (100) surfaces are along the <110> orientation.

In the exemplary embodiments of this invention, and briefly stated, the structure is made using a dual gate integration scheme. In the NFET stack, a tensile metal film (such as a film of TiN) is used. The NFET is on (100) oriented silicon, both for FET performance and stress coupling benefit reasons. The PFET is on one of (110) or (111) oriented silicon for device performance and maximum stress coupling reasons. The sigma zz coefficient for a (100) oriented PFET is weak, whereas this coefficient is much larger in (110) or (111), thereby maximizing the benefit of the vertical stress. Either a conventional HOT A or B, or a super HOT, device type may be employed.

General reference with regard to fabrication of a HOT hybrid-type substrate can be made to commonly owned US 2005/0236687 A1, “Strained Silicon CMOS on Hybrid Crystal Orientations”, incorporated by reference herein in its entirety as though fully restated herein.

General reference with regard to super HOT hybrid-type substrates can be made to M. Yang, et al., “Silicon-on-Insulator MOSFET's with Hybrid Crystal Orientations”, incorporated by reference herein in its entirety as though fully restated herein.

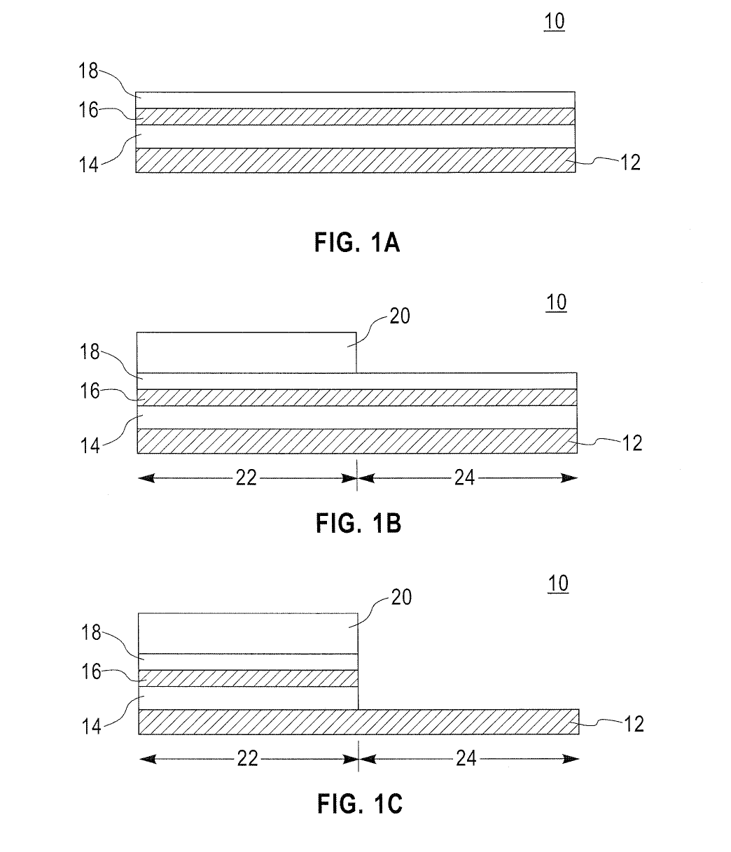

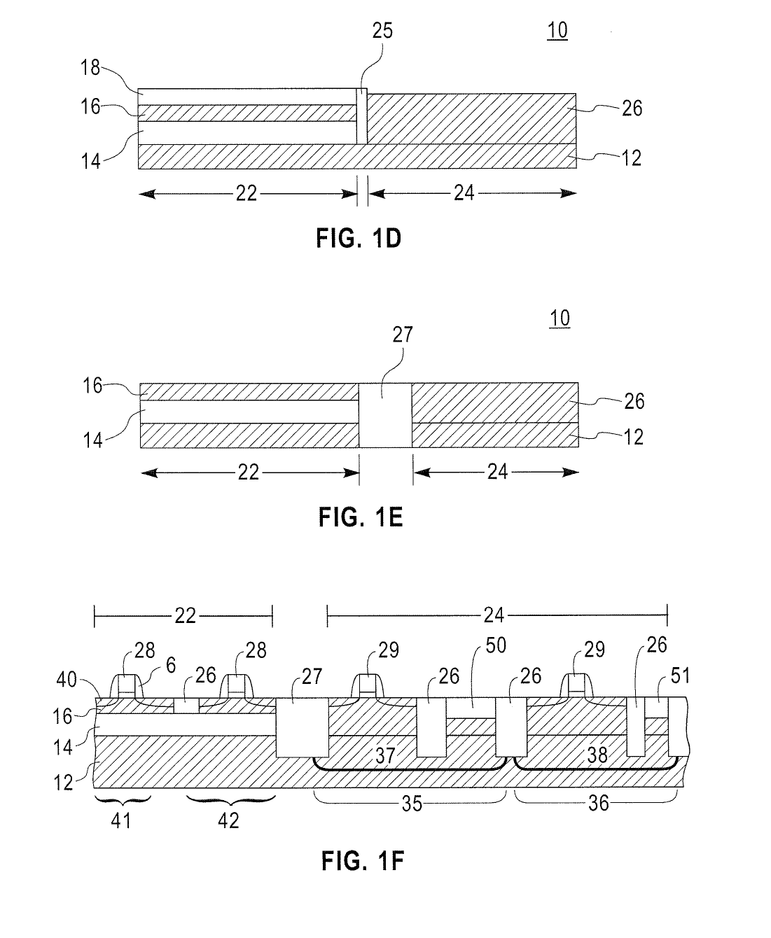

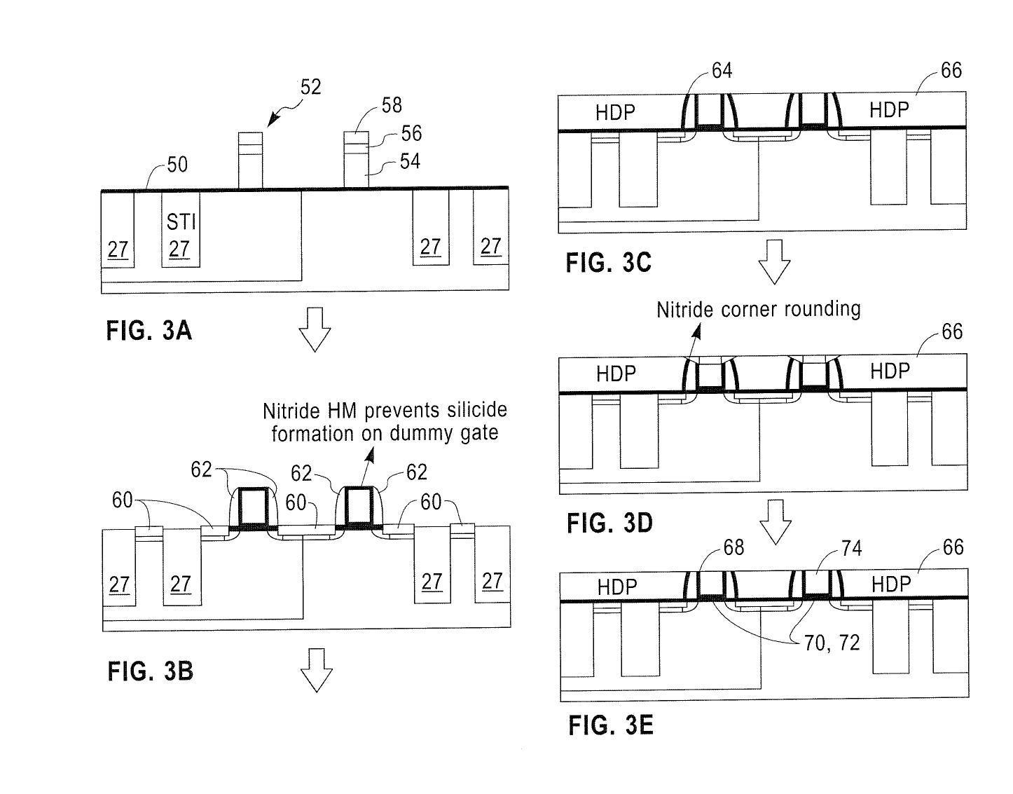

Reference is now made to FIGS. 1A-1F for describing exemplary and non-limiting processing to fabricate a structure that is amenable to modification by the improved and novel process steps shown in FIGS. 3A-3E.

FIG. 1A illustrates a substrate 10, i.e., hybrid substrate, which may be employed. As shown, the substrate 10 includes a surface dielectric layer 18, a first semiconductor layer 16, an insulating layer 14, and a second semiconductor layer 12.

The surface dielectric layer 18 of the substrate 10 is an oxide, nitride, oxynitride or other insulating layer that is either present in one of the initial wafers before bonding, or formed atop the first semiconductor layer 16 after wafer bonding by either a thermal process (i.e., oxidation, nitridation or oxynitridation) or by deposition. Notwithstanding the origin of the surface dielectric layer 18, the surface dielectric layer 18 has a thickness from about 3 nm to about 500 nm, with a thickness from about 5 nm to about 20 nm being more typical.

The first semiconductor layer 16 is comprised of any semiconducting material including, for example, Si, SiC, SiGe, SiGeC, Ge alloys, GaAs, InAs, InP as well as other III/V or II/VI compound semiconductors. First semiconductor layer 16 may also comprise an SOI layer of a preformed SOI substrate or a layered semiconductor such as, for example, Si/SiGe. The first semiconductor layer 16 has the same crystalline orientation as the second semiconductor layer 12, preferably being in the (100) crystal plane. Although a (100) crystal orientation is preferred, the first semiconductor layer 16 may have a (111) crystal plane, (110) crystal plane or other crystal plane, so long as the first semiconducting layer 16 is not a Si-containing material that is subsequently processed to provide an NFET device on a (110) crystal plane.

The thickness of the first semiconductor layer 16 may vary depending on the initial starting wafers used to form the substrate 10. Typically, however, the first semiconductor layer 16 has a thickness from about 5 nm to about 100 nm. The first semiconductor layer 16 is thinned to a desired thickness by planarization, grinding, wet etch, dry etch or any combination thereof. In a preferred embodiment, the first semiconductor layer 16 is thinned by oxidation and wet etching to achieve the desired thickness to provide the upper Si-containing layer. The first semiconductor layer 16 may be thinned to provide an “ultra-thin silicon-on-insulator (UTSOI) substrate”, which denotes a silicon-on-insulating substrate having an upper silicon containing layer (SOI layer) that fully depletes of charge carriers when a FET is formed atop the upper silicon-containing layer and is forward biased. The first semiconductor layer 16 typically has a thickness of less than about 40 nm, more typically less than about 15 nm. The first semiconductor layer 16 is subsequently processed to provide the SOI layer of an UTSOI region of the substrate.

It should be noted, however, that the exemplary embodiments of this invention place no restrictions on the thickness of the layer 16, which may be a UTSOI layer or a thicker layer. However, if the thickness of the first semiconductor layer 16 is reduced, the transfer of stress from a stressed gate electrode will increase, thereby increasing the performance of the device.

The insulating layer 14, which is located between the first semiconductor layer 16 and the second semiconductor layer 12, has a variable thickness depending upon the initial wafers used to create the substrate 10. Typically, however, the insulating layer 14 has a thickness from about 1 nm to about 5 nm, with a thickness from about 500 nm to about 100 nm being more typical. The insulating layer 14 is an oxide or other like insulator material that is formed on one or both of the wafers prior to bonding.

The second semiconductor layer 12 is comprised of any semiconducting material which may be the same or different from that of the first semiconductor layer 16. Thus, second semiconductor layer 12 may include, for example, Si, SiC, SiGe, SiGeC, Ge alloys, GaAs, InAs, InP as well as other III/V or II/VI compound semiconductors. Second semiconductor layer 12 may also comprise an SOI layer of a preformed SOI substrate or a layered semiconductor such as, for example, Si/SiGe. The second semiconductor layer 12 has the same crystalline orientation as the first semiconductor layer 16, preferably being in the (100) crystal plane. Although a (100) crystal orientation is preferred, the second semiconductor layer 12 may have a (111) crystal plane, (110) crystal plane or other crystal plane, so long as the second semiconducting layer 12 is not a Si-containing material that is subsequently processed to provide an nFET device on a (110) crystal plane.

The thickness of the second semiconductor layer 12 may vary depending on the initial starting wafers used to form the substrate 10. Typically, however, the second semiconductor layer 12 has a thickness from about 5 nm to about 200 nm, with a thickness from about 5 to about 100 nm being more typical.

The substrate 10 illustrated in FIG. 1A is comprised of two semiconductor wafers that are bonded together. The two wafers used in fabricating the substrate 10 may include two SOI wafers, wherein one of the wafers includes the first semiconductor layer 16 and the other wafer includes the second semiconductor 12; an SOI wafer and a bulk semiconductor wafer; or an SOI wafer and a bulk wafer which includes an ion implant region, such as a H₂ implant region, which can be used to split a portion of at least one of the wafers during bonding.

Bonding is achieved by first bringing the two wafers into intimate contact with each other, optionally applying an external force to the contacted wafers, and then heating the two contacted wafers under conditions that are capable of bonding the two wafers together. The heating step may be performed in the presence or absence of an external force. The heating step is typically performed in an inert ambient at a temperature from about 200° to about 1050° C. for a time period from about 2 to about 20 hours. More preferably, the bonding is performed at a temperature from about 200° to about 400° C. for a time period from about 2 to about 20 hours. The term “inert ambient” is used to denote an atmosphere in which an inert gas, such as He, Ar, N₂, Xe, Kr or a mixture thereof, is employed. A preferred ambient used during the bonding process is N₂.

In the embodiment where two SOI wafers are employed, some material layers of at least one of the SOI wafers may be removed after bonding utilizing a planarization process such as chemical mechanical polishing (CMP) or grinding and etching. The planarization process stops when the surface dielectric layer 18 is reached.

In the embodiment in which one of the wafers includes an ion implant region, the ion implant region forms a porous region during bonding which causes a portion of the wafer above the ion implant region to break off leaving a bonded wafer such as is shown, for example, in FIG. 1A. The implant region is typically comprised of H₂ ions which are implanted into the surface of the wafer utilizing ion implantation conditions that are well known to those skilled in the art.

In the embodiment where the wafers to be bonded do not include a dielectric layer therein, the surface dielectric layer 18 may be formed atop the bonded wafers by a thermal process, such as oxidation, or by a conventional deposition process, such as chemical vapor deposition (CVD), plasma-enhanced CVD, atomic layer deposition, chemical solution deposition as well as other like deposition processes.

Referring now to FIG. 1B, a mask 20 is formed on a predetermined portion of the substrate 10 of FIG. 1A so as to protect a portion of the substrate 10, while leaving another portion of the substrate 10 unprotected. The protected portion of the substrate 10 defines a SOI region 22 of the substrate, whereas the unprotected portion of the substrate 10 defines a bulk-Si region 24. In one embodiment, the mask 20 is formed on a predetermined portion of the surface dielectric layer 18 by applying a photoresist mask to the entire surface of the substrate 10. After application of the photoresist mask, the mask is patterned by lithography, which includes the steps of exposing the photoresist to a pattern of radiation and developing the pattern utilizing a resist developer. The resultant structure including the mask 20 formed on a predetermined portion of the substrate 10 is shown, for example, in FIG. 1B.

In another embodiment, mask 20 is a nitride or oxynitride layer that is formed and patterned utilizing lithography and etching. The nitride or oxynitride mask 20 may be removed after defining the bulk-Si region 24 of the substrate 10.

After forming the mask 20 atop the substrate 10, the structure is subjected to one or more etching steps so as to expose a surface of the second semiconductor layer 12. Specifically, the one or more etching steps used at this point of the present invention removes the unprotected portions of the surface dielectric layer 18, as well as underlying portions of the first semiconductor layer 16, and a portion of the insulating layer 14 which separates the first semiconductor layer 16 from the second semiconductor layer 12. The etching may be performed utilizing a single etching process or multiple etching steps may be employed. The etching used at this point of the present invention may include a dry etching process such as reactive-ion etching, ion beam etching, plasma etching or laser etching, a wet etching process wherein a chemical etchant is employed or any combination thereof. In a preferred embodiment of the present invention, reactive-ion etching (RIE) is used in selectively removing the unprotected portions of the surface dielectric layer 18, the first semiconductor layer 16 and the insulating layer 14 in the bulk-Si region 24. The resultant structure after the etching process has been performed is shown, for example, in FIG. 1C. Note that the sidewalls of the protected SOI region 22, i.e., the surface dielectric layer 18, the first semiconductor layer 16, the insulating layer 14 and the second semiconductor layer 12, are exposed after this etching step. As shown, the exposed sidewalls of layers 18, 16 and 14 are aligned with an outer most edge of mask 20.

The mask 20 is then removed from the structure shown in FIG. 1C utilizing a conventional resist stripping process and then a liner or spacer 25 is typically formed on the exposed sidewalls. The liner or spacer 25, which is optional, is formed by deposition and etching. The liner or spacer 25 is comprised of an insulating material such as, for example, an oxide.

After forming the optional liner or spacer 25, a semiconductor material 26 is formed on the exposed second semiconductor layer 12. Semiconductor material 26 has a crystallographic orientation that is the same as the crystallographic orientation of the second semiconductor layer 12. The resultant structure is shown, for example, in FIG. 1D.

The semiconductor material 26 may comprise any Si-containing semiconductor, such as Si, strained Si, SiGe, SiC, SiGeC or combinations thereof, which is capable of being formed utilizing a selective epitaxial growth method. In some preferred embodiments, semiconductor material 26 is comprised of Si. The semiconductor material 26 may be referred to as a regrown semiconductor material 26.

Next, the structure shown in FIG. 1D is subjected to a planarization process such as chemical mechanical polishing (CMP) or grinding such that the upper surface of the semiconductor material 26 is substantially planar with the upper surface of the first semiconductor layer 16. Note that a previously protected portion of the surface dielectric layer 18 is removed during this planarization process.

After providing the substantially planar surfaces, an isolation region 27, such as a shallow trench isolation region, is typically formed so as to isolate the SOI device region 22 from the bulk-Si device region 24. The isolation region 27 is formed utilizing processing steps that are well known to those skilled in the art including, for example, trench definition and etching; optionally lining the trench with a diffusion barrier; and filling the trench with a trench dielectric such as an oxide. After the trench fill, the structure may be planarized and an optional densification process step may be performed to densify the trench dielectric.

The resultant substantially planar structure containing isolation region 27 is show, for example, in FIG. 1E. As shown, the structure of FIG. 1E includes an exposed first semiconductor layer 16 within the SOI device region 22 and the regrown semiconductor material 26 within the bulk-Si device region 24, wherein the first semiconductor layer 16 and the semiconductor material 26 have the same crystal orientation, preferably having a surface in the (100) crystal plane.

Referring to FIG. 1F, in a next process step, the SOI region 22 is processed to provide SOI MOSFETs and the bulk-Si region 24 is processed to provide bulk MOSFETs. Note that the process flow of FIG. 1F is modified in accordance with the exemplary embodiments of this invention to provide replacement gate processing, as will be described below in reference to FIGS. 3A-3E.

Prior to processing the SOI region 22 and bulk-Si region 24, device isolation regions may be formed within the substrate 10. Device isolation regions 26 can be provided by selectively etching trenches in the substrate utilizing a conventional dry etching process, such as reactive-ion etching (RIE) or plasma etching, in conjunction with conventional block masks. The device isolation regions 26 provide isolation between within the bulk-Si device region 24 and the SOI device region 22 and are similar to the isolation region 27 that separates the bulk-Si device region 24 from the UTSOI device region 22. Alternatively, the device isolation regions 26 may be field isolation regions. Field isolation regions may be formed using a local oxidation of silicon process.

The SOI region 22 and the bulk-Si region 24 may be individually processed utilizing conventional block mask techniques. A block mask may comprise conventional soft and/or hardmask materials and can be formed using deposition, photolithography and etching. In a preferred embodiment, the block mask comprises a photoresist. A photoresist block mask can be produced by applying a blanket photoresist layer to the substrate 10 surface, exposing the photoresist layer to a pattern of radiation, and then developing the pattern into the photoresist layer utilizing conventional resist developer.

Alternatively, the block mask can be a hardmask material. Hardmask materials include dielectrics systems that may be deposited by chemical vapor deposition (CVD) and related methods. Typically, the hardmask composition includes silicon oxides, silicon carbides, silicon nitrides, silicon carbonitrides, etc. Spin-on dielectrics may also be utilized as a hardmask material including but not limited to: silsequioxanes, siloxanes, and boron phosphate silicate glass (BPSG).

Well regions 37, 38 may be formed in the bulk-Si region 24 by selectively implanting p-type or n-type dopants into the bulk-Si region 24 of the substrate 10, wherein the UTSOI region 22 of the substrate 10 may be protected by a block mask as described above. In the example depicted in FIG. 1F, a PFET bulk-Si device region 35 is implanted to provide an n-type well 37 and an NFET bulk-Si device region 36 is implanted to provide a p-type well 38. The SOI layer may also be selectively implanted in the SOI region 22. In the example depicted by FIG. 1F, a PFET SOI region 41 is implanted to provide a n-type channel region and an NFET SOI region 42 is implanted to provide a p-type channel region.

The gate conductor stacks 28, 29 are then be formed within the SOI region 22 and bulk-Si region 24 by first blanket depositing a gate dielectric layer atop the substrate surface and then depositing a gate conductor layer atop the gate dielectric layer. The gate dielectric layer may comprise any conventional gate dielectric material, such as SiO2, or any high-k gate dielectric material, such as HfO₂. The gate conductor layer may comprise any conductive material, such as doped polysilicon. The gate conductor and gate dielectric layer are then etched using conventional deposition, photolithography, and etch processes to provide gate conductor stacks 28, 29 within the SOI region 22 and bulk-Si region 24 of the substrate 10, as depicted in FIG. 1F. Alternatively, block masks may be used to provide the gate conductor stacks 28 within the SOI region 22 and the gate conductor stacks 29 within the bulk-Si region 24 separately.

In the embodiment depicted in FIG. 1F, during a next series of process steps, SOI MOSFET devices are then selectively formed within the SOI region 22, while the bulk-Si region 24 is protected by a hard or soft block masks. For example, a block-mask provided by patterned photoresist can be formed prior to implantation to preselect the substrate area within the SOI region 22 for the gate conductor and/or source/drain diffusion region 40 doping with one dopant type. The block-mask application and implantation procedure can be repeated to dope selected gate conductors 28, source/drain diffusion regions 40, source/drain extension regions or halo regions (not shown) with different dopant types, such as n-type or p-type dopant. After each implant, the block mask resist may be removed using conventional photoresist strip chemistries. In one preferred embodiment, the pattern and implant process steps may be repeated to provide at least one PFET device 41 and at least one NFET 42 device, in which the PFET and NFET devices 41, 42 are separated by isolation region 26.

Prior to implantation, spacers 6 are formed abutting the gate stacks 28, wherein the width of the spacer may be adjusted to compensate for different diffusion rate of the p-type and n-type dopants. In addition, a raised source and drain (RSD) region can be optionally grown via epitaxial growth and it may be present since it typically is a common feature for certain UTSOI devices to lower silicide contact resistance. Further, the PFET and NFET devices within the SOI region 22 may be processed to provide silicide regions or any other conventional structures typically utilized in ultra-thin channel MOSFETS. Following the formation of the devices 41, 42 within the SOI region 22, the hardmask may be stripped from the bulk-Si region 24 and another hardmask is then formed atop the SOI region 22 of the substrate 10 leaving the bulk-Si region 24 exposed.

The bulk-Si device region 24 can then be processed to provide devices having increased performance on a bulk-Si substrate, as opposed to a SOI region. For example, the bulk-Si region 24 may be processed to provide devices typically common in semiconductor manufacturing, such as resistors; capacitors, including decoupling capacitors, planar capacitors, and deep trench capacitors; diodes; and memory devices, such as dynamic random access memory (DRAM) and embedded dynamic random access memory (eDRAM). The bulk-Si region 24 may comprise body contacts 50, 51. In one example, as depicted in FIG. 1F, the bulk-Si region 24 is processed to provide MOSFETS having body contacts 50, 51.

In the embodiment depicted in FIG. 1F, the bulk-Si region 24 is processed to provide at least one p-type MOSFET 35 and at least one n-type MOSFET 36 each having body contacts 50, 51, in which the p-type MOSFETs 35 are separated from the n-type MOSFETs 36 by device isolation regions 26. Similar to the devices formed within the SOI region 22, the bulk-Si region 24 may be selective implanted to provide p-type MOSFETs 35 and n-type MOSFETs 36 utilizing patterned block masks. Following implantation, body contacts 50, 51 are formed to at least one device within the bulk-Si region 24 of the substrate 10. The body contact 50, 51 to each MOSFET device 35, 36 within the bulk-Si region 24 is in electrical contact to the well region of the device and is separated from the MOSFET's source and drain regions 40 by an isolation region 26.

The body contacts 50, 51 may be formed using photolithography, etching, and deposition. More specifically, body contacts 50, 51 may be formed by patterning a portion of the substrate 10 within the bulk-Si region 24 and etching the exposed surface to form via holes to at least one well region 37, 36 of at least one MOSFET 35, 36. The etch process can be a directional etch, such as reactive-ion etching. Following via formation, body contacts 50, 51 are then formed by depositing a conductive material into the via holes using conventional processing, such as CVD or plating. The conductive material may be doped polysilicon or a conductive metal. The conductive metal may include, but is not limited to: tungsten, copper, aluminum, silver, gold, and alloys thereof. In a preferred embodiment, the body contact 51 to the NFET device 36 is p-type doped polysilicon and the body contact 50 to the PFET device 35 is n-type doped polysilicon.

Turning now to FIGS. 3A-3E, and as was noted above, the processing performed in FIG. 1F is modified to accomplish replacement gate processing to achieve the enhanced hybrid orientation technology (HOT) CMOS structure with a tensile stressed NFET gate stack and a compressively stressed PFET gate stack, where the source of the stress is the metal in a high-k metal gate stack. The use of the hybrid orientation technology beneficially maximizes the vertical stress performance coupling in the PFET device.

FIGS. 3A and 3B show a layer of sacrificial gate oxide 50 formed over the bulk Si region of the substrate. A gate stack is comprised of intrinsic polysilicon 54 having an overlying nitride hardmask (HM) 56 and a layer of tetraethyloxysilane (TEOS) 58. This forms a dummy gate structure 52. The nitride HM 56 prevents silicide formation on the dummy gate structure during deposition of silicide regions 60. A gate spacer 62 is also formed. FIG. 3C shows the formation of a nitride stop layer 64 over the over the surface and the over the gate spacer 62, followed by high density plasma (HDP) CVD formation of oxide layer 66.

The HDP CVD formation may follow techniques known in the art. It is typically performed at a temperature from 400-500 C. The HDP is a particularly suited for filling gaps, as it tends to deposit more on the horizontal surfaces than on vertical ones. The typical thicknesses for the HDP oxide may range from 30-200 nm, which is generally the same height as the gate stack.

The HDP CVD formation is followed in FIGS. 3D and 3E by CMP removal of the nitride HM 56 on the dummy gate structure, the etching away of the polysilicon 54 of the dummy gate structure (thereby leaving openings in the HDP oxide layer 66), and the re-deposition of high-k gate oxide (e.g., HfO₂) and metal. This latter process entails an optional formation of a carbonyl metal liner 68 in the etched openings, the formation of the gate high-k oxide layer 70 and metal gate 72, and a CVD metal 74 (e.g., W). The gate metal may be, for example, TaN, TiN, TaAlN, TiAlN, or mixtures thereof.

The formation of the gate high-k oxide layer may be performed using a number of techniques known to the art, such as chemical vapor deposition and atomic layer deposition. The temperature of deposition may range between 250 and 350 C.

General reference with regard to formation of the gate high-k oxide layer can be made to commonly owned U.S. patent Application Publication US 2006/0237796, incorporated by reference herein in its entirety as though fully restated herein.

The metals used may be selected depending on the gate structure being created. For example, when creating NFETs compressive metals may be used, while when creating PFETs tensile metals may be used. The metal thicknesses should range between 5 and 20 nm. These metals may be deposited using PVD in a temperature range from room temperature to 300 C; CVD done in a temperature range from 250 to 550 C, or other methods known in the art.

Additionally, the etching away of the polysilicon 54 of the dummy gate structure may be performed using a number of processes, including RIE techniques and wet chemical techniques.

It can be noted that a TiN film formed by a PVD process exhibits about 2.7 GPA (compressive) as deposited, while a TiN film formed by CVD process is tensile between about 2-5 to about 5 GPA (depending on process and thickness). TaN films behave similarly.

The resulting HOT CMOS structure exhibits the tensile stressed NFET gate stack and the compressively stressed PFET gate stack, where the source of the stress is the metal in the high-k/metal gate stack, where the use of the hybrid orientation technology beneficially maximizes the vertical stress performance coupling in the PFET device.

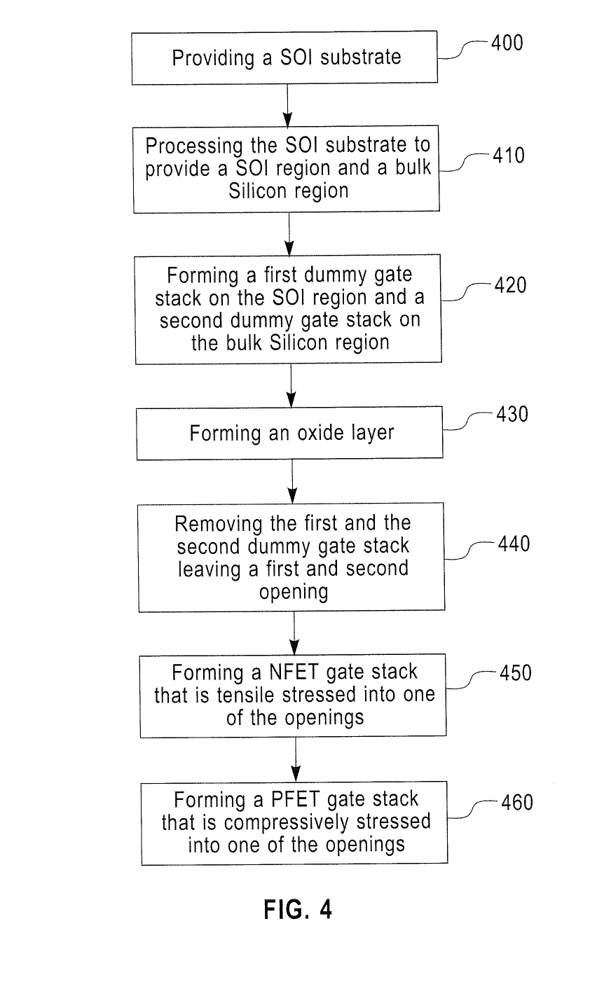

FIG. 4 shows a method in accordance with one exemplary embodiment of this invention which is used to form a hybrid orientation technology CMOS structure. In step 400 a SOI substrate is provided. The SOI is processed to provide a SOI region and a bulk Silicon region in step 410. In step 420 a first dummy gate stack is formed on the SOI region and a second dummy gate stack is formed on the bulk Silicon region. An oxide layer is formed in step 430. In step 440, a replacement gate process is used to remove the first and the second dummy gate stack. This leaves a first and second opening. A high dielectric constant gate oxide, a metal gate, and a metal fill are deposited into one of the openings to form an NFET gate stack that is tensile stressed in step 450. In step 460, a high dielectric constant gate oxide, a metal gate, and a metal fill are deposited into the other opening to form a PFET gate stack that is compressively stressed.

In the method described above, the NFET gate stack may be formed above (100) Silicon and the PFET gate stack may be formed above (110) or (111) Silicon.

Furthermore the high dielectric constant gate oxide may be formed of HfO₂ and formed using chemical vapor deposition or atomic layer deposition. Alternatively the gate oxide may be composed of other high dielectric constant materials, such as Ta₂O₅, TiO₂, Al₂0₃, Y₂O₃ and La₂O₅.

In the method described above the metal gates may have a thickness of less than 10 nm and may be comprised of TiN, Ta, TaN, TaCN, TaSiN, TaSi, AlN, W or Mo. In a non-limiting example the metal in the NFET gate stack is comprised of TaN or TiN that is deposited by plasma vapor deposition in a compressive state and the metal in the PFET gate stack is comprised of TaN or TiN that is deposited by chemical vapor deposition in a tensile state.

Furthermore the intrinsic polysilicon layer of the dummy gate may be removed using wet chemical techniques. Additionally the oxide layer may be formed using high density plasma chemical vapor deposition.

The method as described above is used in the fabrication of integrated circuit chips.

Various modifications and adaptations may become apparent to those skilled in the relevant arts in view of the foregoing description, when read in conjunction with the accompanying drawings and the appended claims. As but some examples, the use of other similar or equivalent materials and/or processing equipment may be attempted by those skilled in the art. However, all such and similar modifications of the teachings of this invention will still fall within the scope of this invention.

Further, the various disclosed layer thicknesses and ranges of thicknesses, processing temperatures, cleaning and etching compositions and the like are intended to be read in an exemplary sense, and not as imposing limitations on the practice of the exemplary embodiments of this invention.

Furthermore, some of the features of the examples of this invention may be used to advantage without the corresponding use of other features. As such, the foregoing description should be considered as merely illustrative of the principles, teachings, examples and exemplary embodiments of this invention, and not in limitation thereof.

What is claimed is:

1. A hybrid orientation technology CMOS structure comprising a tensile stressed NFET gate stack and a compressively stressed PFET gate stack, where each gate stack is comprised of a high dielectric constant oxide/metal, and where the source of the stress in the tensile stressed NFET gate stack and the compressively stressed PFET gate stack is the metal in the high-k metal gate stack.

2. The hybrid orientation technology CMOS structure of claim 1, where the metal in the NFET gate stack is comprised of one of TaN and TiN that is deposited by plasma vapor deposition in a compressive state.

3. The hybrid orientation technology CMOS structure of claim 1, where the metal in the PFET gate stack is comprised of one of TaN and TiN that is deposited by chemical vapor deposition in a tensile state.

4. The hybrid orientation technology CMOS structure of claim 1, where the NFET gate stack is formed above (100) Silicon.

5. The hybrid orientation technology CMOS structure of claim 6, where the (100) Silicon is an epitaxial Silicon layer grown on a Silicon substrate.

6. The hybrid orientation technology CMOS structure of claim 6, where the (100) Silicon is a Silicon layer formed over a layer of oxide.

7. The hybrid orientation technology CMOS structure of claim 1, where the PFET gate stack is formed above one of (110) or (111) Silicon.

8. The hybrid orientation technology CMOS structure of claim 9, where the (110) or (111) Silicon is an epitaxial Silicon layer grown on a Silicon substrate.

9. The hybrid orientation technology CMOS structure of claim 9, where the (110) or (111) Silicon is a Silicon layer formed over a layer of oxide.

10. The hybrid orientation technology CMOS structure of claim 6, where the Silicon has a thickness of 15 nm or less.

11. The hybrid orientation technology CMOS structure of claim 9, where the Silicon has a thickness of 15 nm or less.

12. A method to form a hybrid orientation technology CMOS structure comprising:
providing a SOI substrate;
processing the SOI substrate to provide a SOI region and a bulk Silicon region;
forming a first dummy gate stack on the SOI region and a second dummy gate stack on the bulk Silicon region;
forming an oxide layer;
using a replacement gate process to remove the first and the second dummy gate stacks leaving a first opening and a second opening;
depositing a high dielectric constant gate oxide, a metal gate, and a metal fill into one of the openings to form a NFET gate stack that is tensile stressed; and
depositing a high dielectric constant gate oxide, a metal gate, and a metal fill into the other opening to form a PFET gate stack that is compressively stressed.

13. The method of claim 12, where the NFET gate stack is formed above (100) Silicon.

14. The method of claim 12, where the PFET gate stack is formed above one of (110) or (111) Silicon.

15. The method of claim 12, where the high dielectric constant gate oxide is HfO₂ and is formed using one of chemical vapor deposition and atomic layer deposition.

16. The method of claim 12, where the metal gate has a thickness of less than 10 nm.

17. The method of claim 12, where the oxide layer is formed using high density plasma chemical vapor deposition.

18. The method of claim 12, where the metal in the NFET gate stack is comprised of one of TaN and TiN that is deposited by plasma vapor deposition in a compressive state.

19. The method of claim 12, where the metal in the PFET gate stack is comprised of one of TaN and TiN that is deposited by chemical vapor deposition in a tensile state.

20. The method of claim 12, where the Silicon layer of the SOI has a thickness of 15 nm or less.
